(19) United States
(12) Patent Application Publication
(10) Pub. No.: US 2006/0035092 A1
(43) Pub. Date: Feb. 16, 2006

(54) Resin composition for sealing LED elements and cured product generated by curing the composition

(75) Inventors: Hisashi Shimizu, Annaka-shi (JP); Tsutomu Kashiwagi, Annaka-shi (JP); Toshio Shiobara, Annaka-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Shin-Etsu Chemical Co., Ltd., Tokyo (JP)

(21) Appl. No.: 11/199,175

(22) Filed: Aug. 9, 2005

(30) Foreign Application Priority Data
Aug. 10, 2004 (JP) 2004-233778

(51) Int. Cl. B32B 27/04; C08L 83/04; H01L 21/00

(52) U.S. Cl. 428/447; 524/863; 528/14

(57) ABSTRACT

Provided is a resin composition for sealing LED elements, including (i) an organopolysiloxane with a polystyrene equivalent weight average molecular weight of at least 5×10³, represented by an average composition formula (1): R¹ₐ(OX)_{b}SiO_{(4-a-b)/2}, in which, each R¹ represents, independently, an alkyl group, alkenyl group or aryl group of 1 to 6 carbon atoms, each X represents, independently, a hydrogen atom, or an alkyl group, alkenyl group, alkoxyalkyl group or acyl group of 1 to 6 carbon atoms, a represents a number within a range from 1.05 to 1.5, b represents a number that satisfies 0<b<2, and 1.05<a+b<2), and (ii) a condensation catalyst. Also provided are a cured product produced by curing the composition and a process for sealing LED elements with the cured product. The composition exhibits excellent thermal resistance, ultraviolet light resistance, optical transparency, toughness and adhesion.

### BACKGROUND OF THE INVENTION

1. Field of the Invention

The present invention relates to an optical material, and more particularly to a resin composition for sealing LED (light-emitting diode) elements that exhibits excellent characteristics such as thermal resistance, optical transparency and toughness, as well as a cured product thereof and a process for sealing LED elements with the cured product.

2. Description of the Prior Art

Due to their favorable workability and ease of handling, highly transparent epoxy resins and silicone resins are widely used as sealing materials for LED elements.

Recently however, LEDs with shorter wavelengths such as blue LEDs and ultraviolet LEDs have been developed, and the potential applications for these diodes are expanding rapidly. Under these circumstances, conventional epoxy resins and silicone resins present various problems, including yellowing of the resin under strong ultraviolet light, or even rupture of the resin skeleton in severe cases, meaning such resins can no longer be used. In the case of ultraviolet LED applications, resin sealing is particularly problematic, meaning sealing with glass is currently the only viable option.

### SUMMARY OF THE INVENTION

Accordingly, an object of the present invention is to provide a resin composition for sealing LED elements that exhibits excellent thermal resistance, ultraviolet light resistance, optical transparency, toughness and adhesion, as well as a cured product thereof and a process for sealing LED elements with the cured product.

As a result of intensive research aimed at achieving the above object, the inventors of the present invention discovered that the composition described below, and a cured product thereof, were able to achieve the above object. In other words, the present invention provides a resin composition for sealing LED elements, comprising:
(i) an organopolysiloxane with a polystyrene equivalent weight average molecular weight of at least 5×10³, represented by an average composition formula (1) shown below:
   R¹ₐ(OX)_{b}SiO_{(4-a-b)/2} (1)
   (wherein, each R¹ represents, independently, an alkyl group, alkenyl group or aryl group of 1 to 6 carbon atoms, each X represents, independently, a hydrogen atom, or an alkyl group, alkenyl group, alkoxyalkyl group or acyl group of 1 to 6 carbon atoms, a represents a number within a range from 1.05 to 1.5, b represents a number that satisfies 0<b<2, and 1.05<a+b<2), and
(ii) a condensation catalyst.

Furthermore, the present invention also provides a cured product obtained by curing the above composition and a process for sealing LED elements with the cured product.

A composition and cured product of the present invention exhibit excellent thermal resistance, ultraviolet light resistance, optical transparency, toughness and adhesion, and also have a small birefringence. Accordingly, they are particularly useful for sealing LED elements.

### DETAILED DESCRIPTION OF THE PREFERRED EMBODIMENTS

As follows is a more detailed description of the present invention. In this description, room temperature is defined as 24±2° C. (that is, 22 to 26° C.).

[(i) Organopolysiloxane]

The component (i) is an organopolysiloxane with a polystyrene equivalent weight average molecular weight of at least 5×10³, represented by an average composition formula (1) shown below.
R¹ₐ(OX)_{b}SiO_{(4-a-b)/2} (1)
(wherein, each R¹ represents, independently, an alkyl group, alkenyl group or aryl group of 1 to 6 carbon atoms, each X represents, independently, a hydrogen atom, or an alkyl group, alkenyl group, alkoxyalkyl group or acyl group of 1 to 6 carbon atoms, a represents a number within a range from 1.05 to 1.5, b represents a number that satisfies 0<b<2, and 1.05<a+b<2)

In the above formula (1), examples of suitable alkyl groups represented by R¹ include a methyl group, ethyl group, propyl group, isopropyl group, butyl group, isobutyl group, tert-butyl group, pentyl group, neopentyl group, hexyl group, or cyclohexyl group. An example of a suitable alkenyl group is a vinyl group, allyl group, or propenyl group, and a vinyl group is particularly suitable. An example of a suitable aryl group is a phenyl group. Of these, a methyl group or phenyl group is preferred as the R¹ group.

In the above formula (1), examples of suitable alkyl groups represented by X include a methyl group, ethyl group, propyl group, isopropyl group, butyl group, or isobutyl group. An example of a suitable alkenyl group is a vinyl group. Examples of suitable alkoxyalkyl groups include a methoxyethyl group, ethoxyethyl group, or butoxyethyl group. Examples of suitable acyl groups include an acetyl group or propionyl group. Of these, a hydrogen atom, methyl group or isobutyl group is preferred as the X group.

In the above formula, a is preferably a number within a range from 1.15 to 1.25, and b is preferably a number that satisfies 0.01≦b<1.4, and even more preferably 0.02≦b≦1.0, and most preferably 0.05≦b ≦0.3. If the value of a is less than 1.05, then cracks are more likely to form in the cured coating, whereas if the value exceeds 1.5, the cured coating loses toughness, and is prone to becoming brittle. If b is zero, then the adhesiveness relative to substrates deteriorates, whereas if b is 2 or greater, a cured coating may be unobtainable. Furthermore, the value of a+b preferably satisfies 1.06≦a+b≦1.8, and even more preferably 1.1≦a+b≦1.7.

Furthermore, in order to ensure a more superior level of thermal resistance for the obtained cured product, the (mass referenced) proportion of R¹ groups such as methyl groups within the organopolysiloxane of this component is preferably reduced, and specifically, is preferably restricted to no more than 32% by mass, more preferably 15 to 32% by mass, even more preferably 20 to 32% by mass, and particularly preferably 25 to 31% by mass. If the proportion of the R¹ groups falls within this range, the cured coating may be easily obtainable, and the resulting cured coating tends to display superior levels of crack resistance.

The organopolysiloxane of this component can be produced either by hydrolysis-condensation of a silane compound represented by a general formula (2) shown below:
SiR²_{c}(OR³)_{4-c} (2)
(wherein, each R² represents, independently, a group as defined above for R¹, each R³ represents, independently, a group as defined above for X, and c represents an integer of 1 to 3), or by cohydrolysis-condensation of a silane compound represented by the above general formula (2), and an alkyl silicate represented by a general formula (3) shown below:
Si(OR³)₄ (3)
(wherein, each R³ represents, independently, a group as defined above) and/or a condensation polymerization product of the alkyl silicate (an alkyl polysilicate). Both the silane compound and the alkyl (poly)silicate may be used either alone, or in combinations of two or more different materials.

Examples of the silane compound represented by the above formula (2) include methyltrimethoxysilane, methyltriethoxysilane, ethyltrimethoxysilane, ethyltriethoxysilane, phenyltrimethoxysilane, phenyltriethoxysilane, dimethyldimethoxysilane, dimethyldiethoxysilane, diphenyldimethoxysilane, diphenyldiethoxysilane, methylphenyldimethoxysilane and methylphenyldiethoxysilane, and of these, methyltrimethoxysilane is preferred. These silane compounds may be used either alone, or in combinations of two or more different compounds.

Examples of the alkyl silicate represented by the above formula (3) include tetraalkoxysilanes such as tetramethoxysilane, tetraethoxysilane and tetraisopropyloxysilane, and examples of the condensation polymerization product of the alkyl silicate (the alkyl polysilicate) include methyl polysilicate and ethyl polysilicate. These alkyl (poly)silicates may be used either alone, or in combinations of two or more different materials.

Of these possibilities, the organopolysiloxane of this component is preferably formed from 50 to 95 mol % of an alkyltrialkoxysilane such as methyltrimethoxysilane, and 50 to 5 mol % of a dialkyldialkoxysilane such as dimethyldimethoxysilane, as such a composition ensures superior levels of crack resistance and thermal resistance in the resulting cured product. Organopolysiloxanes formed from 75 to 85 mol % of an alkyltrialkoxysilane such as methyltrimethoxysilane, and 25 to 15 mol % of a dialkyldialkoxysilane such as dimethyldimethoxysilane are even more desirable.

In a preferred embodiment of the present invention, the organopolysiloxane of this component can be obtained either by hydrolysis-condensation of the silane compound described above, or by cohydrolysis-condensation of the silane compound and an alkyl (poly)silicate, and although there are no particular restrictions on the method used for the reaction, the conditions described below represent one example of a suitable method.

The above silane compound and alkyl (poly)silicate are preferably dissolved in an organic solvent such as an alcohol, ketone, ester, cellosolve or aromatic compound prior to use. Specific examples of preferred solvents include alcohols such as methanol, ethanol, isopropyl alcohol, isobutyl alcohol, n-butanol and 2-butanol, and of these, isobutyl alcohol is particularly preferred, as it produces superior levels of curability for the resulting composition, and excellent toughness of the cured product.

In addition, the above silane compound and alkyl (poly)silicate preferably undergo hydrolysis-condensation in the presence of an acid catalyst such as acetic acid, hydrochloric acid, or sulfuric acid. The quantity of water added during the hydrolysis-condensation is typically within a range from 0.9 to 1.5 mols, and preferably from 1.0 to 1.2 mols, relative to each mol of the combined quantity of alkoxy groups within the silane compound and the alkyl (poly)silicate. If this blend quantity falls within the range from 0.9 to 1.5 mols, then the resulting composition exhibits excellent workability, and the cured product exhibits excellent toughness.

The polystyrene equivalent weight average molecular weight of the organopolysiloxane of this component is preferably set, using aging, to a molecular weight just below the level that results in gelling, and from the viewpoints of ease of handling and pot life, must be at least 5×10³, and preferably within a range from least 5×10³ to 3×10⁶, and even more preferably from 1×10⁴ to 1×10⁵. If this molecular weight is less than 5×10³, then the composition is prone to cracking on curing. If the molecular weight is too large, then the composition becomes prone to gelling, and the workability deteriorates.

The temperature for conducting the aging described above is preferably within a range from 0 to 40° C., and is even more preferably room temperature. If the aging temperature is from 0 to 40° C., then the organopolysiloxane of this component develops a ladder-type structure, which provides the resulting cured product with excellent crack resistance.

The organopolysiloxane of this component may use either a single compound, or a combination of two or more different compounds.

[(ii) Condensation Catalyst]

The condensation catalyst of the component (ii) is necessary to enable curing of the organopolysiloxane of the component (i). There are no particular restrictions on the condensation catalyst, although in terms of achieving favorable stability for the organopolysiloxane, and excellent levels of hardness and resistance to yellowing of the resulting cured product, an organometallic catalyst is normally used. Examples of this organometallic catalyst include compounds that contain zinc, aluminum, titanium, tin, or cobalt atoms, and more specifically include organic acid zinc compounds, Lewis acid catalysts, organoaluminum compounds, and organotitanium compounds. Specific examples include zinc octoate, zinc benzoate, zinc p-tert-butylbenzoate, zinc laurate, zinc stearate, aluminum chloride, aluminum perchlorate, aluminum phosphate, aluminum triisopropoxide, aluminum acetylacetonate, aluminum butoxy-bis(ethylacetoacetate), tetrabutyl titanate, tetraisopropyl titanate, tin octoate, cobalt naphthenate, and tin naphthenate, and of these, zinc octoate is preferred.

The blend quantity of the component (ii) is typically within a range from 0.05 to 10 parts by mass per 100 parts by mass of the component (i), although in terms of obtaining a composition with superior levels of curability and stability, a quantity within a range from 0.1 to 5 parts by mass is preferred.

The condensation catalyst of this component may use either a single compound, or a combination of two or more different compounds.

[Other Optional Components]

In addition to the aforementioned component (i) and component (ii), other optional components can also be added to a composition of the present invention, provided such addition does not impair the actions or effects of the present invention. Examples of these other optional components include inorganic fillers, inorganic phosphors, age resistors, radical inhibitors, ultraviolet absorbers, adhesion improvers, flame retardants, surfactants, storage stability improvers, antiozonants, photostabilizers, thickeners, plasticizers, coupling agents, antioxidants, thermal stabilizers, conductivity imparting agents, antistatic agents, radiation blockers, nucleating agents, phosphorus-based peroxide decomposition agents, lubricants, pigments, metal deactivators, physical property modifiers, and organic solvents. These optional components may be used either alone, or in combinations of two or more different materials.

Adding an inorganic filler provides a number of effects, including ensuring that the light scattering properties of the cured product and the fluidity of the composition fall within appropriate ranges, and strengthening materials that use the composition. There are no particular restrictions on the type of inorganic filler used, although very fine particulate fillers that do not impair the optical characteristics are preferred, and specific examples include alumina, aluminum hydroxide, fused silica, crystalline silica, ultra fine amorphous silica powder, ultra fine hydrophobic silica powder, talc, calcium carbonate, and barium sulfate.

Examples of suitable inorganic phosphors include the types of materials that are widely used in LEDs, such as yttrium aluminum garnet (YAG) phosphors, ZnS phosphors, Y₂O₂S phosphors, red light emitting phosphors, blue light emitting phosphors, and green light emitting phosphors.

[Example of Form of Composition]

In the simplest embodiment, the resin composition for sealing LED elements according to the present invention comprises the aforementioned components (i) and (ii) and does not comprise inorganic fillers such as silica fillers, and particularly consists essentially of the aforementioned components (i) and (ii). Examples of the inorganic fillers include those stated above.

[Preparation of Composition, Cured Product]

A composition of the present invention can be prepared by mixing together the component (i), the component (ii), and any optional components that are to be added, using any arbitrary mixing method. Specifically, the organopolysiloxane of the component (i), the condensation catalyst of the component (ii), and any optional components are normally placed in a commercially available mixer (such as a Thinky Conditioning Mixer, manufactured by Thinky Corporation), and the composition of the present invention is then prepared by mixing the components for approximately 1 to 5 minutes to produce a uniform mixture.

The composition of the present invention may be formed into a film in neat form, or may also be dissolved in an organic solvent to generate a varnish. There are no particular restrictions on the organic solvent used, although a solvent with a boiling point of at least 64° C. is preferred, and specific examples of suitable solvents include hydrocarbon-based solvents such as benzene, toluene, and xylene; ether-based solvents such as tetrahydrofuran, 1,4-dioxane, and diethyl ether; ketone-based solvents such as methyl ethyl ketone; halogen-based solvents such as chloroform, methylene chloride, and 1,2-dichloroethane; alcohol-based solvents such as methanol, ethanol, isopropyl alcohol, and isobutyl alcohol; as well as octamethylcyclotetrasiloxane and hexamethyldisiloxane, and of these, xylene and isobutyl alcohol are preferred. The organic solvent may use either a single compound, or a combination of two or more different solvents.

There are no particular restrictions on the blend quantity of the organic solvent, although a quantity that results in a concentration for the organopolysiloxane of the component (i) of at least 30% by mass, and even more preferably 40% by mass or higher, is desirable, as such a quantity simplifies the processing required to produce a typical thickness for the cured product within a range from 10 μm to 3 mm, and even more typically from 100 μm to 3 mm.

Furthermore, when curing the composition, the curing can be conducted, for example, at 80 to 200° C. for about 1 to about 12 hours, and a step cure process is preferably conducted across a range from 80 to 200° C. For example, the step cure process can be conducted with two steps or three or more steps and preferably with the following three steps. First, the composition is subjected to low temperature curing at 80 to 120° C. The curing time may be within a range from about 0.5 to about 2 hours. Subsequently, the composition is heat cured at 125 to 175° C. The curing time may be within a range from about 0.5 to about 2 hours. Finally, the composition is heat cured at 180 to 200° C. The curing time may be within a range from about 1 to about 10 hours. More specifically, the composition is preferably first subjected to low temperature curing at 80° C. for 1 hour, subsequently heat cured at 150° C. for a further 1 hour, and then heat cured at 200° C. for 8 hours. By using step curing with these stages, the composition exhibits superior curability, and the occurrence of foaming can be suppressed to a suitable level. Furthermore, by using the step curing, a colorless, transparent cured product with a thickness stated above can be obtained.

The glass transition temperature (Tg) of the cured product obtained by curing a composition of the present invention is usually too high to enable measurement using a commercially available measuring device (for example, the thermomechanical tester (brand name: TM-7000) manufactured by Shinku Riko Co., Ltd. has a measurement range from 25 to 200° C.), indicating that the obtained cured product exhibits an extremely high level of thermal resistance.

[Applications for Composition, Cured Product]

A composition of the present invention is useful for sealing LED elements, and particularly for sealing blue LED and ultraviolet LED elements. LED elements can be sealed with a cured product of the composition of the present invention by a process comprising the steps of:

applying said composition to said LED elements and

curing said composition to form said cured product on said LED elements, thereby sealing said LED elements with said cured product. The composition can be applied to the LED elements, for example, in neat form or in the form of a varnish generated by dissolving the composition in an organic solvent as stated above. The composition can be cured, for example, using step curing as stated above.

Because the composition exhibits excellent levels of thermal resistance, ultraviolet light resistance, and transparency, it can also be used in a variety of other applications described below, including display materials, optical recording materials, materials for optical equipment and optical components, fiber optic materials, photoelectronic organic materials, and peripheral materials for semiconductor integrated circuits.

-1. Display Materials-

Examples of display materials include peripheral materials for liquid crystal display devices, including films for use with liquid crystals such as substrate materials for liquid crystal displays, optical wave guides, prism sheets, deflection plates, retardation plates, viewing angle correction films, adhesives, and polarizer protection films; sealing materials, anti-reflective films, optical correction films, housing materials, front glass protective films, substitute materials for the front glass, adhesives and the like for the new generation, flat panel, color plasma displays (PDP); substrate materials, optical wave guides, prism sheets, deflection plates, retardation plates, viewing angle correction films, adhesives, and polarizer protection films and the like for plasma addressed liquid crystal (PALC) displays; front glass protective films, substitute materials for the front glass, and adhesives and the like for organic EL (electroluminescence) displays; and various film substrates, front glass protective films, substitute materials for the front glass, and adhesives and the like for field emission displays (FED).

-2. Optical Recording Materials-

Examples of optical recording materials include disk substrate materials, pickup lenses, protective films, sealing materials, and adhesives and the like for use with VD (video disks), CD, CD-ROM, CD-R/CD-RW, DVD±R/DVD±RW/DVD-RAM, MO, MD, PD (phase change disk), and optical cards.

-3. Materials for Optical Equipment-

Examples of materials for optical instruments include lens materials, finder prisms, target prisms, finder covers, and light-receiving sensor portions and the like for steel cameras; lenses and finders for video cameras; projection lenses, protective films, sealing materials, and adhesives and the like for projection televisions; and lens materials, sealing materials, adhesives, and films and the like for optical sensing equipment.

-4. Materials for Optical Components-

Examples of materials for optical components include fiber materials, lenses, waveguides, element sealing agents and adhesives and the like around optical switches within optical transmission systems; fiber optic materials, ferrules, sealing agents and adhesives and the like around optical connectors; sealing agents and adhesives and the like for passive fiber optic components and optical circuit components such as lenses, waveguides and LED elements; and substrate materials, fiber materials, element sealing agents and adhesives and the like for optoelectronic integrated circuits (OEIC).

-5. Fiber Optic Materials-

Examples of fiber optic materials include illumination light guides for decorative displays; industrial sensors, displays and indicators; and fiber optics for transmission infrastructure or household digital equipment connections.

-6. Peripheral Materials for Semiconductor Integrated Circuits-

Examples of peripheral materials for semiconductor integrated circuits include resist materials for microlithography for generating LSI and ultra LSI materials.

-7. Photoelectronic Organic Materials-

Examples of photoelectronic organic materials include peripheral materials for organic EL elements; organic photorefractive elements; optical-optical conversion devices such as optical amplification elements, optical computing elements, and substrate materials around organic solar cells; fiber materials; and sealing agents and adhesives for the above types of elements.

### EXAMPLES

As follows is a more detailed description of the present invention using a series of examples, although the present invention is in no way limited by these examples.

The methyltrimethoxysilane used in the synthesis examples is KBM13 (a brand name) manufactured by Shin-Etsu Chemical Co., Ltd., and the dimethyldimethoxysilane is KBM22 (a brand name), also manufactured by Shin-Etsu Chemical Co., Ltd.

### Synthesis Example 1

A stirrer and a condenser tube were fitted to a 1 L three-neck flask. This flask was then charged with 109 g (0.8 mols) of methyltrimethoxysilane, 24 g (0.2 mols) of dimethyldimethoxysilane, and 106 g of isobutyl alcohol, and the mixture was cooled in ice with constant stirring. With the temperature inside the reaction system maintained at 0 to 20° C., 60.5 g of 0.05 N hydrochloric acid solution was added dropwise. Following completion of the dropwise addition, the reaction mixture was stirred for 7 hours under reflux at 80° C. Subsequently, the reaction solution was cooled to room temperature, and 150 g of xylene was added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and following adjustment of the volatile fraction to 50% by mass, the solution was aged for 12 hours at room temperature, yielding 118 g (including the organic solvent, non-volatile fraction: 50% by mass) of an organopolysiloxane 1 with a weight average molecular weight of 21,000, represented by a formula (4) shown below:
(CH₃)_{1.2}(OX)_{0.18}SiO_{1.31} (4)
(wherein, X represents a combination of hydrogen atoms, methyl groups, and isobutyl groups).

### Synthesis Example 2

A stirrer and a condenser tube were fitted to a 1 L three-neck flask. This flask was then charged with 68.1 g (0.5 mols) of methyltrimethoxysilane, 60.1 g (0.5 mols) of dimethyldimethoxysilane, and 118 g of isobutyl alcohol, and the mixture was cooled in ice with constant stirring. With the temperature inside the reaction system maintained at 0 to 20° C., 54 g of 0.05 N hydrochloric acid solution was added dropwise. Following completion of the dropwise addition, the reaction mixture was stirred for 7 hours under reflux at 80° C. Subsequently, the reaction solution was cooled to room temperature, and 150 g of xylene was added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and following adjustment of the volatile fraction to 50% by mass, the solution was aged for 12 hours at room temperature, yielding 109 g (including the organic solvent, non-volatile fraction: 50% by mass) of an organopolysiloxane 2 with a weight average molecular weight of 8,500, represented by a formula (5) shown below:
(CH₃)_{1.5}(OX)_{0.15}SiO_{1.18} (5)
(wherein, X represents a combination of hydrogen atoms, methyl groups, and isobutyl groups).

### Synthesis Example 3

A stirrer and a condenser tube were fitted to a 1 L three-neck flask. This flask was then charged with 115.8 g (0.85 mols) of methyltrimethoxysilane, 18.0 g (0.15 mols) of dimethyldimethoxysilane, and 102 g of isobutyl alcohol, and the mixture was cooled in ice with constant stirring. With the temperature inside the reaction system maintained at 0 to 20° C., 78.3 g of 0.05 N hydrochloric acid solution was added dropwise. Following completion of the dropwise addition, the reaction mixture was stirred for 7 hours under reflux at 80° C. Subsequently, the reaction solution was cooled to room temperature, and 150 g of xylene was added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and following adjustment of the volatile fraction to 50% by mass, the solution was aged for an extended period (120 hours) at room temperature, yielding 102 g (including the organic solvent, non-volatile fraction: 50% by mass) of an organopolysiloxane 3 with a weight average molecular weight of 120,000, represented by a formula (6) shown below:
(CH₃)_{1.15}(OX)_{0.19}SiO_{1.33} (6)
(wherein, X represents a combination of hydrogen atoms, methyl groups, and isobutyl groups).

### Synthesis Example 4

A stirrer and a condenser tube were fitted to a 1 L three-neck flask. This flask was then charged with 109 g (0.8 mols) of methyltrimethoxysilane, 24 g (0.2 mols) of dimethyldimethoxysilane, and 106 g of isobutyl alcohol, and the mixture was cooled in ice with constant stirring. With the temperature inside the reaction system maintained at 0 to 20° C., 60.5 g of 0.05 N hydrochloric acid solution was added dropwise. Following completion of the dropwise addition, the reaction mixture was stirred for 7 hours under reflux at 80° C. Subsequently, the reaction solution was cooled to room temperature, and 100 g of hexamethyldisiloxane and 50 g of xylene were added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and following adjustment of the volatile fraction to 50% by mass, the solution was aged for 12 hours at room temperature, yielding 113 g (including the organic solvent, non-volatile fraction: 50% by mass) of an organopolysiloxane 4 with a weight average molecular weight of 20,500, represented by a formula (7) shown below:
(CH₃)_{1.2}(OX)_{0.19}SiO_{1.31} (7)
(wherein, X represents a combination of hydrogen atoms, methyl groups, and isobutyl groups).

### Synthesis Example 5

A stirrer and a condenser tube were fitted to a 1 L three-neck flask. This flask was then charged with 27.2 g (0.2 mols) of methyltrimethoxysilane, 96.2 g (0.8 mols) of dimethyldimethoxysilane, and 106 g of isobutyl alcohol, and the mixture was cooled in ice with constant stirring. With the temperature inside the reaction system maintained at 0 to 20° C., 57.1 g of 0.05 N hydrochloric acid solution was added dropwise. Following completion of the dropwise addition, the reaction mixture was stirred for 7 hours under reflux at 80° C. Subsequently, 150 g of xylene was added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and the volatile fraction was adjusted to 50% by mass, yielding 94 g (including the organic solvent, non-volatile fraction: 50% by mass) of an organopolysiloxane C1 with a weight average molecular weight of 15,000, represented by a formula (8) shown below:
(CH₃)_{1.8}(OX)_{0.11}SiO_{1.05} (8)
(wherein, X represents a combination of hydrogen atoms, methyl groups, and isobutyl groups).

### Synthesis Example 6

A stirrer and a condenser tube were fitted to a 1 L three-neck flask. This flask was then charged with 136.2 g (1.0 mols) of methyltrimethoxysilane and 106 g of isobutyl alcohol, and the mixture was cooled in ice with constant stirring. With the temperature inside the reaction system maintained at 0 to 20° C., 81 g of 0.05 N hydrochloric acid solution was added dropwise. Following completion of the dropwise addition, the reaction mixture was stirred for 7 hours under reflux at 80° C. Subsequently, the reaction solution was cooled to room temperature, and 150 g of xylene was added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and following adjustment of the volatile fraction to 50% by mass, the solution was aged for 12 hours at room temperature, yielding 103 g (including the organic solvent, non-volatile fraction: 50% by mass) of an organopolysiloxane C2 with a weight average molecular weight of 22,500, represented by a formula (9) shown below:
(CH₃)_{1.0}(OX)_{0.21}SiO_{1.40} (9)
(wherein, X represents a combination of hydrogen atoms, methyl groups, and isobutyl groups).

### Synthesis Example 7

A stirrer and a condenser tube were fitted to a 1 L three-neck flask. This flask was then charged with 109 g (0.8 mols) of methyltrimethoxysilane, 24 g (0.2 mols) of dimethyldimethoxysilane, and 106 g of isobutyl alcohol, and the mixture was cooled in ice with constant stirring. With the temperature inside the reaction system maintained at 0 to 20° C., 60.5 g of 0.05 N hydrochloric acid solution was added dropwise. Following completion of the dropwise addition, the reaction mixture was stirred for 24 hours at room temperature. Subsequently, 150 g of xylene was added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and following adjustment of the volatile fraction to 50% by mass, the solution was aged for 12 hours at room temperature, yielding 109 g (including the organic solvent, non-volatile fraction: 50% by mass) of an organopolysiloxane C3 with a weight average molecular weight of 2,700, represented by a formula (10) shown below:
(CH₃)_{1.2}(OX)_{1.16}SiO_{0.82} (10)
(wherein, X represents a combination of hydrogen atoms, methyl groups, and isobutyl groups).

### Synthesis Example 8

A stirrer and a condenser tube were fitted to a 1 L three-neck flask. This flask was then charged with 40.9 g (0.3 mols) of methyltrimethoxysilane, 170.8 g (0.7 mols) of diphenyldimethoxysilane, and 106 g of isobutyl alcohol, and the mixture was cooled in ice with constant stirring. With the temperature inside the reaction system maintained at 0 to 20° C., 55.1 g of 0.05 N hydrochloric acid solution was added dropwise. Following completion of the dropwise addition, the reaction mixture was stirred for 7 hours under reflux at 80° C. Subsequently, 150 g of xylene was added to dilute the reaction solution. The reaction solution was then poured into a separating funnel, and washed repeatedly with 300 g samples of water until the electrical conductivity of the separated wash water fell to no more than 2.0 μS/cm. The water was then removed from the washed reaction solution by azeotropic distillation, and the volatile fraction was adjusted to 50% by mass, yielding 124 g (including the organic solvent, non-volatile fraction: 50% by mass) of an organopolysiloxane C4 with a weight average molecular weight of 13,800, represented by a formula (11) shown below:
(CH₃)_{0.3}(C₆H₅)_{1.4}(OX)_{0.12}SiO_{1.09} (11)
(wherein, X represents a combination of hydrogen atoms, methyl groups, and isobutyl groups).

### Examples 1 to 6, Comparative Examples 1 to 4

Compositions were prepared by blending the organopolysiloxanes 1 to 4, and C1 to C4 (including the organic solvent) obtained in the synthesis examples 1 to 8 with condensation catalysts, in the proportions shown in Table 1. These compositions were cured, and the characteristics (crack resistance, adhesion, UV irradiation resistance test, and thermal resistance) of the resulting cured products were tested and evaluated in accordance with the methods described below. The results are shown in Tables 1 and 2.

<Evaluation Methods>

-1. Crack Resistance-

Each of the prepared compositions was placed in a Teflon (registered trademark) coated mold of dimensions 50 mm×50 mm×2 mm, subsequently subjected to step curing at 80° C. for 1 hour, 150° C. for 1 hour, and 200° C. for 1 hour, and then post-cured for 8 hours at 200° C., thus yielding a cured film of thickness 1 mm. The cured film was inspected visually for the presence of cracks. If no cracks were visible in the cured film, the crack resistance was evaluated as “good”, and was recorded as A, whereas if cracks were detected, the resistance was evaluated as “poor”, and was recorded as B. Furthermore, if a cured film was not able to be prepared, a “measurement impossible” evaluation was recorded as C.

-2. Adhesion-

Each of the prepared compositions was applied to a glass substrate using an immersion method, subsequently subjected to step curing at 80° C. for 1 hour, 150° C. for 1 hour, and 200° C. for 1 hour, and then post-cured for 8 hours at 200° C., thus forming a cured product film of thickness 2 to 3 μm on top of the glass substrate. Using a cross-cut adhesion test, the adhesion of the cured product to the glass substrate was investigated. Furthermore, in those cases where cracks had developed in the cured product, making adhesion measurement impossible, the result was recorded in the table as x.

-3. UV Irradiation Resistance Test

Each of the prepared compositions was dripped onto a glass substrate using a dropper, subsequently subjected to step curing at 80° C. for 1 hour, 150° C. for 1 hour, and 200° C. for 1 hour, and then post-cured for 8 hours at 200° C., thus forming a cured product on top of the glass substrate. This cured product was then irradiated with UV radiation (30 mW) for 24 hours using a UV irradiation device (brand name: Eye Ultraviolet Curing Apparatus, manufactured by Eyegraphics Co., Ltd.). The surface of the cured product following UV irradiation was then inspected visually. If absolutely no deterioration of the cured product surface was noticeable, the UV resistance was evaluated as “good”, and was recorded as A, if some deterioration was noticeable, an evaluation of “some deterioration” was recorded as B, and if significant deterioration was noticeable, an evaluation of “deterioration” was recorded as C.

-4. Thermal Resistance

Each of the prepared compositions was placed in a Teflon (registered trademark) coated mold of dimensions 50 mm×50 mm×2 mm, subsequently subjected to step curing at 80° C. for 1 hour, 150° C. for 1 hour, and 200° C. for 1 hour, and then post-cured for 8 hours at 200° C., thus yielding a cured film of thickness 1 mm. This cured film was then placed in an oven at 250° C., and the residual weight reduction ratio (%) was measured after 500 hours in the oven. This residual weight reduction ratio was recorded as the thermal resistance (%). Furthermore, in those cases where preparation of the cured film was impossible, the result was recorded in the table as x.

TABLE 1

| | | Example | | | | | |
|---|---|---|---|---|---|---|---|
| | | 1 | 2 | 3 | 4 | 5 | 6 |
| (i) | Organopolysiloxane 1 | 10(5) | | | 10(5) | 10(5) | |
| | Organopolysiloxane 2 | | 10(5) | | | | |
| | Organopolysiloxane 3 | | | 10(5) | | | |
| | Organopolysiloxane 4 | | | | | | 10(5) |
| (ii) | Catalyst 1 | 0.02 | 0.02 | 0.02 | | | 0.02 |
| | Catalyst 2 | | | | 0.02 | | |
| | Catalyst 3 | | | | | 0.02 | |

| | | | | | | |
|---|---|---|---|---|---|---|
| Methyl group content (%)* | 26.0 | 31.5 | 25.1 | 26.0 | 26.0 | 26.0 |
| Weight average molecular weight | 21,000 | 8,500 | 120,000 | 21,000 | 21,000 | 20,500 |
| Crack resistance | A | A | A | A | A | A |
| Adhesion | 100/100 | 100/100 | 100/100 | 100/100 | 100/100 | 100/100 |
| UV irradiation resistance test | A | A | A | A | A | A |
| Thermal resistance (%) | 98 | 95 | 99 | 98 | 98 | 98 |

(Units: parts by mass)

-Component (i)

The numbers within parentheses in the table represent the blend quantity (parts by mass) of the organopolysiloxane with the volatile fraction removed.

-Component (ii)

Catalyst 1: zinc octoate

Catalyst 2: aluminum butoxy-bis(ethylacetoacetate)

Catalyst 3: tetrabutyl titanate

-Composition

*Methyl Group Content: Theoretical Quantity of Methyl Groups Within the Polysiloxane.

TABLE 2

| | | Comparative Example | | | |
|---|---|---|---|---|---|
| | | 1 | 2 | 3 | 4 |
| (i) | Organopolysiloxane C1 | 10(5) | | | |
| | Organopolysiloxane C2 | | 10(5) | | |
| | Organopolysiloxane C3 | | | 10(5) | |
| | Organopolysiloxane C4 | | | | 10(5) |
| (ii) | Catalyst 1 | 0.02 | 0.02 | 0.02 | 0.02 |

| | | | | |
|---|---|---|---|---|
| Methyl group content (%)* | 40.5 | 22.4 | 26.0 | 6.7 |
| Weight average molecular weight | 15,000 | 22,500 | 2,700 | 13,800 |
| Crack resistance | A | B | B | A |
| Adhesion | 50/100 | x | x | 60/100 |
| UV irradiation resistance test | B | A | A | C |
| Thermal resistance (%) | 85 | x | x | 93 |

(Units: parts by mass)

-Component (i)

The numbers within parentheses in the table represent the blend quantity (parts by mass) of the organopolysiloxane with the volatile fraction removed.

-Component (ii)

Catalyst 1: Zinc Octoate

-Composition

*Methyl Group Content: Theoretical Quantity of Methyl Groups Within the Polysiloxane.

<Evaluations>

As is evident from Table 1, the resin compositions for sealing LED elements according to the present invention can be cured to form thick-film cured products, and display good levels of adhesion, crack resistance, UV irradiation resistance, and thermal resistance, and thus exhibit excellent properties as resin compositions for sealing LED elements.

On the other hand, as is clear from Table 2, the organopolysiloxanes of the comparative examples 1, 2, and 4, which do not satisfy the requirements of the aforementioned average composition formula (1), and the organopolysiloxane of the comparative example 3, which does not satisfy the aforementioned weight average molecular weight requirement, all suffer problems, including exhibiting inferior performance within at least one of the categories of adhesion, crack resistance, UV irradiation resistance, and thermal resistance, or being unable to generate the targeted cured product.

What is claimed is:

1. A resin composition for sealing LED elements, comprising:
(i) an organopolysiloxane with a polystyrene equivalent weight average molecular weight of at least 5×10³, represented by an average composition formula (1) shown below:
R¹ₐ(OX)_{b}SiO_{(4-a-b)/2} (1)
(wherein, each R¹ represents, independently, an alkyl group, alkenyl group or aryl group of 1 to 6 carbon atoms, each X represents, independently, a hydrogen atom, or an alkyl group, alkenyl group, alkoxyalkyl group or acyl group of 1 to 6 carbon atoms, a represents a number within a range from 1.05 to 1.5, b represents a number that satisfies 0<b<2, and 1.05<a+b<2), and
(ii) a condensation catalyst.

2. The composition according to claim 1, wherein said composition does not comprise an inorganic filler.

3. The composition according to claim 1, wherein said R¹ groups are methyl groups.

4. The composition according to claim 1, wherein a proportion of said R¹ groups within said organopolysiloxane is no more than 32% by mass.

5. The composition according to claim 1, wherein said organopolysiloxane is dissolved in an organic solvent with a boiling point of at least 64° C., and a concentration of said organopolysiloxane is at least 30% by mass.

6. The composition according to claim 1, wherein said condensation catalyst is an organometallic catalyst.

7. The composition according to claim 6, wherein said organometallic catalyst comprises zinc, aluminum or titanium atoms.

8. The composition according to claim 7, wherein said organometallic catalyst is zinc octoate.

9. A cured product obtained by curing the composition according to claim 1.

10. A colorless, transparent cured product with a thickness from 10 μm to 3 mm, obtained by curing the composition according to claim 1 at a temperature of at least 180° C.

11. A colorless, transparent cured product with a thickness from 10 μm to 3 mm, obtained by curing the composition according to claim 1 by a step curing conducted across a range from 80 to 200° C.

12. A process for sealing LED elements with a cured product of the composition according to claim 1, comprising the steps of:
applying said composition to said LED elements and
curing said composition to form said cured product on said LED elements, thereby sealing said LED elements with said cured product.
